(19) United States
(12) Patent Application Publication
(10) Pub. No.: US 2020/0068718 A1
(43) Pub. Date: Feb. 27, 2020

(54) METHOD FOR APPLYING AN ELECTRICAL MICROSTRUCTURE, ELASTOMER STRUCTURE, FIBER COMPOSITE COMPONENT, AND TIRE

(71) Applicant: GOTTFRIED WILHELM LEIBNIZ UNIVERSITÄT HANNOVER, Hannover (DE)

(72) Inventors: Hans Jürgen MAIER, Neustadt a. Rbge. (DE); Marc Christopher WURZ, Hannover (DE); Sebastian BENGSCH, Hannover (DE)

(21) Appl. No.: 16/466,472

(22) PCT Filed: Nov. 21, 2017
(86) PCT No.: PCT/EP2017/079938

§ 371 Date: Jun. 4, 2019

(30) Foreign Application Priority Data
Dec. 8, 2016 (DE) 10 2016 123 795.7

(51) Int. Cl. H05K 3/30; H05K 1/18; B60C 23/04

(52) U.S. Cl. CPC H05K 3/303; H05K 1/181; H05K 2201/0317; H05K 2203/0156; H05K 2203/0264; B60C 23/0493

(57) ABSTRACT

The invention relates to a method for applying an electrical microstructure on or in an object of any type, wherein the electrical microstructure is first applied to a flexible film and the film is fastened, with the electrical microstructure applied thereto in front, to a fastening surface of the object by adhesive bonding and/or vulcanization attachment. The invention further relates to an elastomer structure, to a fiber composite component, and to a motor-vehicle tire, each having at least one electrical microstructure fastened thereto by adhesive bonding and/or vulcanization attachment.

The invention relates to a method as claimed in claim 1 for applying an electrical microstructure on or in an object of arbitrary type. The invention furthermore relates to an elastomer structure, to a fiber composite component and to a tire, respectively having at least one electrical microstructure adhesively bonded thereon or vulcanized in.

A microstructure refers to structures configured with an electrical functionality, for example conductive tracks, interconnections, electrical connection pads or simple electrical and/or electronic components, which respectively have individual dimensions in the micrometer range, in particular dimensions of less than 10 μm. The application of such an electrical microstructure on or in an object of arbitrary type may, depending on the complexity and shape of this object, entail particular difficulties or seem impossible with previous technology. Such electrical microstructures are produced for example by vapor deposition processes, for example sputtering. The systems required therefor are relatively complex and large. Furthermore, with such systems is scarcely possible to coat arbitrary end products efficiently on an industrial manufacturing scale. Depending on the shape of the object, for example in the case of corresponding cavities, direct coating of the object may in any event seem difficult or scarcely possible.

The object of the invention is therefore to provide a method for applying an electrical microstructure on or in an object of arbitrary type, which allows reliable fastening of the electrical microstructure on the object and represents a production method suitable for mass production.

This object is achieved by a method for applying an electrical microstructure on or in an object of arbitrary type, wherein the electrical microstructure is initially applied on a flexible film, and the film with the electrical microstructure applied thereon forward is fastened on a fastening surface of the object by adhesive bonding and/or vulcanizing in. The invention has the advantage that arbitrary objects can now be provided with such electrical microstructures even in mass production. The application or integration of such electrical microstructures on objects of arbitrary type has great advantages, since because of the small dimensions and the low mass of such an electrical microstructure, the properties of the object are not altered, or are altered in a scarcely perceptible way. The use of a flexible film has the advantage that it can be applied without problems on an arbitrary, even curved body.

With the electrical microstructure and/or the electrical and/or electronic components fastened thereon, in principle arbitrary components and therefore circuit arrangements can be produced, for example components with piezo effects, SMD components, components with SAW effects.

The process according to invention is, for example, suitable for the production of vehicle tires or other tires having, applied thereon or integrated therein, tire sensors which are based on the electrical microstructure. Such tire sensors can be applied reliably on the tires by the method according to the invention without generating imbalances or other defects therein, and are suitable for the sensing of a multiplicity of physical quantities, apart from the tire pressure in particular also for monitoring a tire profile and other kinematic quantities, in particular deformations of the tire. In this way, the provision of an energy-efficient and reliable tire is possible in an improved way.

The invention makes these and other advantages possible because the electrical microstructure is not immediately fastened directly on the fastening surface of the object, i.e. is not directly vapor-deposited there. Instead, according to the invention division can take place of the manufacturing processes into preparation of the film with the electrical microstructure applied thereon and, in a manufacturing step chronologically and/or spatially separated therefrom, applying the electrical microstructure on the fastening surface of the object. The flexible film with the electrical microstructure applied thereon may therefore be provided as a prepared (semifinished) product and used as required in the corresponding amount in the production of the object of arbitrary type. In this case, the respectively optimal conditions for the manufacturing steps may be provided in each production substep. During the production of the flexible film with the electrical microstructure applied thereon, suitable conditions may be provided for the use of a vapor deposition system, for example by the film being fed in the form of a band through a deposition space, or being situated on a roll and coated on this roll with the electrical microstructure. During the application of the electrical microstructure on the fastening surface of the object, the suitable conditions for production of the object may then be maintained, for example the conventional ambient conditions during tire manufacture. These are highly compatible with the application of an electrical microstructure with said film on the fastening surface, for example the inner side of the tire, by adhesive bonding and/or vulcanizing in.

A further advantage is that the step of applying the electrical microstructure with the film on the fastening surface of the object is possible under normal factory conditions. In particular, clean-room conditions are not required. A further advantage is that the invention allows automated application of the electrical microstructure onto objects of arbitrary type.

Since an electrical microstructure has extremely small dimensions, work hardening problems also do not occur at the point of connection between the electrical microstructure to the object or in the electrical microstructure. The electrical microstructure may, in particular, comprise one or more metal layers. The metal layers may respectively consist of one metal or of different metals. The layer height of the electrical microstructure may, for example, lie in the range of from 10 nm to 1 μm.

The object to be provided with the electrical microstructure, in particular its fastening surface, may be electrically nonconductive in nature. The fastening surface may in particular be configured as a nonmetallic surface, for example by an insulating coating being applied. The film may be configured as a film of any type. In particular, films of plastic material are suitable for carrying out the invention.

According to one advantageous refinement of the invention, after the fastening of the electrical microstructure on the object, the film is removed fully or partially, in particular mostly. This has the advantage that the properties of the object provided with the electrical microstructure are no longer, or at least no longer substantially, influenced by the film during subsequent operation. The film may, for example, be removed by mechanically separating it fully or partially from the electrical microstructure.

According to one advantageous refinement of the invention, the film is removed by dissolving the film. This has the advantage that the removal of the film is carried out relatively gently, so that damage to the electrical microstructure or its fastening on the object can be avoided.

According to one advantageous refinement of the invention, the film is wetted by means of a solvent and thereby dissolved, and/or the the film is dissolved by heating. In this way, the film can be removed particularly gently. The solvent used is to be matched to the chemical properties of the film. For example, a water-soluble film, for example of polyvinyl alcohol (PVA), may advantageously be used as the film. After application of the electrical microstructure on the fastening surface of the object, such a film can be dissolved by water and correspondingly washed away. If the film is intended to be fully or partially dissolve by heating, for example a thermo-release film may be used. This is advantageous in particular for a more complex construction.

According to one advantageous refinement of the invention, the film is perforated and/or comprises holes. This has the advantage that the presence of the film does not interfere, or scarcely interferes, with the subsequent construction of the object, for example when it is constructed in multiple layers and the film with the electrical microstructure is embedded between different layers. For example, by corresponding perforation or holing of the film, assembly of different layers of the object may be carried out, for example if the object is configured as a fiber composite component constructed with a plurality of fiber layers. In this way, the matrix bond in a fiber composite component may be ensured in spite of the film. In such cases, the film may also remain in the object.

The electrical microstructure may be applied on the film, and optionally processed further, by one or more of the following methods, including in combination with one another:
vapor deposition, for example PVD, CVD;
printing, for example by screen printing;
spraying, for example by airbrushing.

PVD stands for physical vapor deposition, CVD for chemical vapor deposition. Desired structuring of the electrical microstructure may be carried out during this application process, for example by using a corresponding mask. As an alternative or in addition, structuring may also be carried out after the process of applying the layer onto the film for example by laser structuring.

According to one advantageous refinement of the invention, the electrical microstructure is applied on the film by means of a vapor deposition process. This allows efficient production of the flexible film with the electrical microstructure in a batch process.

According to one advantageous refinement of the invention, the electrical microstructure comprises conductive tracks, connecting surfaces for electrical and/or electronic components, and/or passive electrical and/or electronic components. In this way, a relatively complex electrical microstructure with a corresponding electrical functionality may be provided. The electronic components may, for example, contain sensor components of all types, for example in the form of strain gauge strips. Furthermore, antenna structures, which may be used for a wireless energy supply of the circuit formed with the electrical microstructure, may be formed by the electrical microstructure. Likewise, data transmission may be carried out wirelessly by means of this antenna structure.

According to one advantageous refinement of the invention, a layer of an interlayer material having electrical and/or electronic components embedded in recesses of the interlayer material is initially applied onto the film, and the electrical microstructure is applied thereon. In this way, even a relatively complex electrical and/or electronic circuit, for example with semiconductor components, may be applied on the fastening surface of the object in the manufacturing process mentioned in the introduction. In this case, the preparation of this circuit is likewise carried out separately from the process of application onto the fastening surface of the object. This is achieved by initially applying the interlayer material with corresponding recesses, for example by corresponding masking, and the electrical and/or electronic components embedded therein onto the film in the separate manufacturing process. The electrical microstructure is then applied thereon, for example by a deposition process. For example, a thermally releasable film, for example the aforementioned thermo-release film, is suitable for such a production process. The interlayer material may, for example, be formed from a material which can be dissolved by means of a solvent, for example from polyvinyl alcohol.

According to one advantageous refinement of the invention, the object on which the electrical microstructure is applied comprises a layer structure of at least two layers, the electrical microstructure is applied on a fastening surface of one of the layers, and the other layers are subsequently arranged thereover, so that the electrical microstructure is embedded between the at least two layers. In this way, the electrical microstructure may be applied on the object while being protected particularly well. If the object is a tire, for example, the electrical microstructure may be arranged between different rubber layers in the layer structure of the tire. For adhesive bonding of the electrical microstructure on the fastening surface of the object, in principle any type of adhesive may be used, although it is necessary to ensure that the adhesive is suitably compatible with the material of the fastening surface. It has been found that, for many objects, in particular for tires, a cyanoacrylate adhesive may advantageously be used.

According to one advantageous refinement of the invention, an adhesive, which is cured by adding a curing agent, is used for firmly adhesively bonding the electrical microstructure on the fastening surface of the object. The curing agent may be a curing agent of any type. It may also be moisture contained in the air, so that the curing agent is this moisture, or water. Such a curing agent interacts, for example, with cyanoacrylate adhesives. The adhesive may also be an adhesive comprising two or more components, so that the curing agent may be a separate curer.

According to one advantageous refinement of the invention, the curing agent is the same as a solvent by which the film can be removed by dissolving. This has the advantage that, by adding the curing agent, the film can at the same time be dissolved and therefore removed. If a cyanoacrylate is used as adhesive, for example, some water may be deliberately added to promote the curing, so that, simultaneously, the curing process takes place and the film is dissolved.

According to one advantageous refinement of the invention, the electrical microstructure comprises at least one sensor component. In this way, a certain additional technical functionality, namely a sensing or measuring function may at the same time be achieved by the application of the electrical microstructure. The sensor component may, for example be a pressure sensor or a strain gauge strip.

The object of arbitrary type mentioned in the introduction on which the electrical microstructure is to be applied, may be an arbitrary technical or other object. The invention is suitable, in particular, for objects which comprise or consist of an elastomer structure or a fiber composite component. In the case of an elastomer structure, this may be a rubber layer, for example a rubber layer of a motor vehicle tire or of another tire. In the case of an elastomer structure, the electrical microstructure may be adhesively bonded. Vulcanizing in is also possible, so that a separate adhesive is required.

In the case of a fiber composite component, the electrical microstructure may likewise be adhesively bonded with a separate adhesive. It is also possible for the electrical microstructure to be adhesively bonded by laminating it in directly with the resin of the fiber composite component. The fiber composite component may, for example, be a carbon-fiber (CF) or glass-fiber (GF) component, as well as textile materials.

The object may in particular be configured as a tire of a motor vehicle, an aircraft or another drivable vehicle. In this case, the electrical microstructure may be firmly adhesively bonded or vulcanized in on the tire inner side or embedded between different layers of the tire. The advantages explained in the introduction can also be achieved in this way.

It is, in particular, possible to apply a plurality of electrical microstructures over the circumference of the tire. A circumferential arrangement of such structures then in particular, makes it possible to obtain data relating to the entire tire circumference.

In the course of tire production, the application according to the invention of the electrical microstructure on the fastening surface may in particular be carried out before a process of vulcanizing tire material, which means that, after the introduction of the electrical microstructure, a further rubber layer may be applied thereon.

The invention will be explained in more detail below with exemplary embodiments with the use of drawings, in which

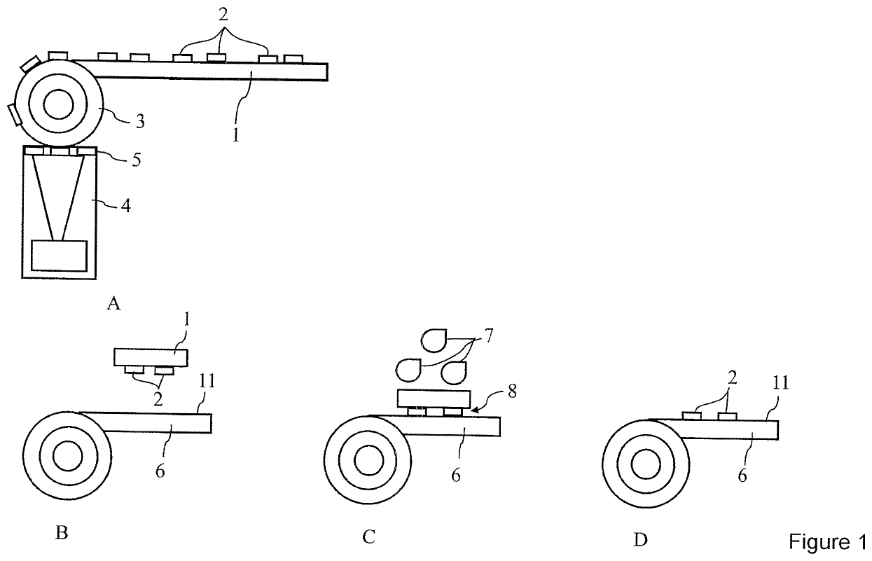

FIG. 1 shows a multistage production process,

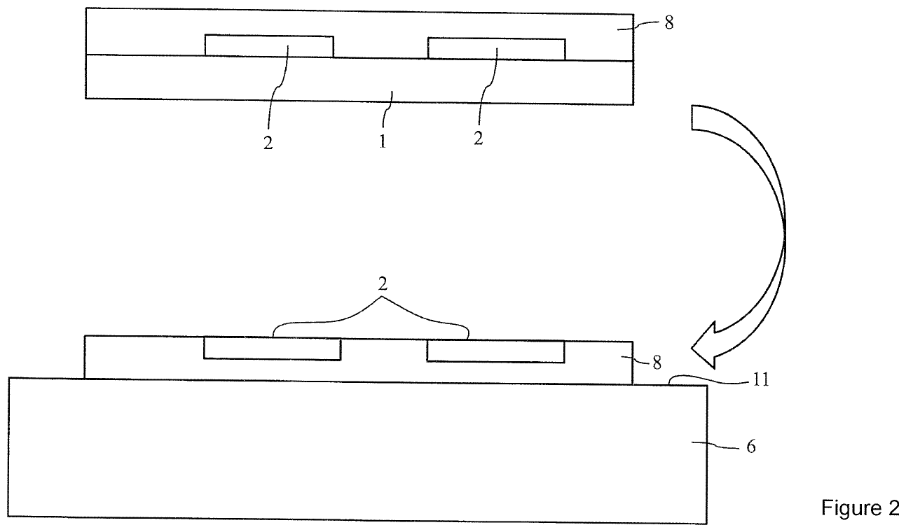

FIG. 2 shows a first embodiment of the application of an electrical microstructure on a fastening surface,

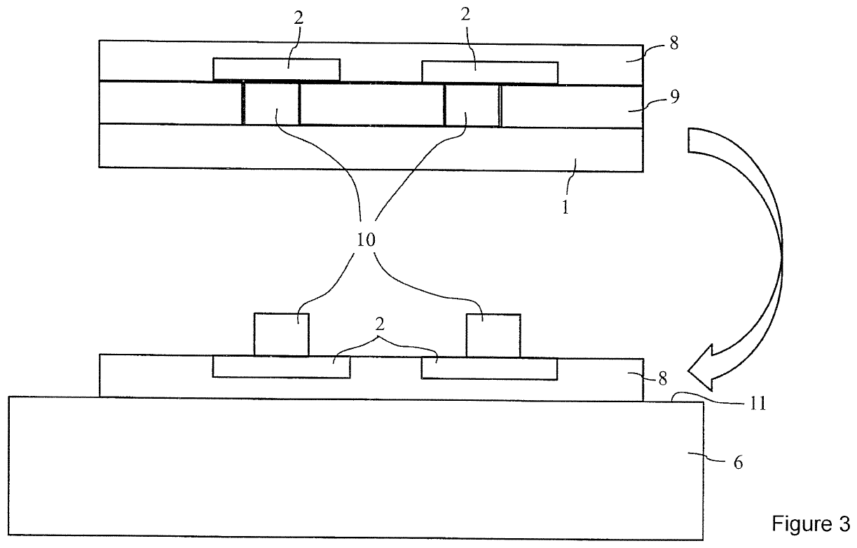

FIG. 3 shows a second embodiment of the application of an electrical microstructure on a fastening surface, and

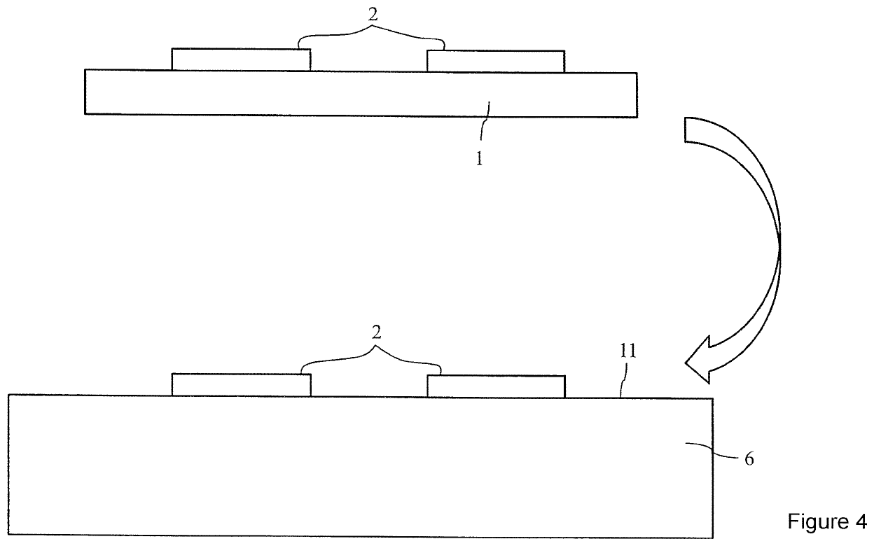

FIG. 4 shows a third embodiment of the application of an electrical microstructure on a fastening surface.

In the figures, the same references are used for elements which correspond to one another.

First, FIG. 1 shows a production step A in which a flexible film 1 is coated by vapor deposition, here by a PVD process, by means of a coating system 4 with an electrical microstructure 2. The film 1 is in this case unrolled from a roll 3. During the process of unrolling the film 1 from the roll 3, the outer film layer of the roll 3 is respectively coated by means of the coating system 4. The coating system 4 comprises a shadow mask 5, by means of which the corresponding structuring of the electrical microstructure 2 is produced.

The application of the electrical microstructure 2 on the film 1 may also be carried out in such a way that the film 1 is exposed to the coating system 4 in the flat unrolled state. The film 1 coated with the electrical microstructure 2 may then be rolled up to form a roll 3 for transport purposes.

Production steps B, C, D relate to the application of the electrical microstructure 2 on an object 6, in this case on a rubber web unrolled from a roll. In step B, the film 1 previously prepared in step A is therefore applied, in the rotated state compared with Figure A, with the electrical microstructure 2 forward on a fastening surface 11 of the object 6. Step C shows that the electrical microstructure 2 is firmly adhesively bonded on the fastening surface 11 by adding adhesive 8. Water 7 may be added to dissolve the film 1 and in order to activate the adhesive 8. Step D shows the final state after the dissolving of the film 1. The electrical microstructure 2 remains on the fastening surface 11 of the object 6.

FIG. 2 shows steps B, C, D of FIG. 1 in an enlarged detail representation. The film 1 with the electrical microstructure 2 applied thereon can again be seen. It can furthermore be seen that adhesive 8, for example cyanoacrylate is applied on the side of the film 1 coated with the electrical microstructure 2. This arrangement is then rotated and applied with the adhesive layer 8 forward onto the fastening surface 11 of the object 6. The lower part of FIG. 2 shows the final state after the film 1 is removed. The object 6, in this case the rubber web, may be an already vulcanized rubber material.

FIG. 3 shows an alternative process for applying an electrical microstructure 2. In this case, the electrical microstructure has already been constructed in a more complex manner in the preceding production step A, by already applying electrical and electronic components 10, for example SMD components and/or piezo components on a contact layer of this microstructure 2. This was carried out in production step A by for example using a thermally removable film as the film 1. The latter was coated with a layer of interlayer material 9. In this interlayer material 9 there are recesses into which the components 10 were inserted. The actual microstructure 2, which in this case represents a contact layer, is then applied by means of the coating system 4.

In the subsequent steps B, C, D, a procedure comparable to that explained above is then carried out. The adhesive layer 8 is applied onto the microstructure 2. The entire arrangement is rotated and applied with the adhesive layer 8 forward onto the fastening surface 11 of the object 6. The adhesive is activated. The film 1 is thermally removed. The layer of the interlayer material 9 is then removed, for example using a solvent. If a water-soluble material such as PVA is used as the interlayer material 9, the removal of the interlayer material may be carried out by a washing with water.

FIG. 3 shows a variant of the application of the electrical microstructure 2 on an object 6 in the form of a not yet vulcanized rubber layer. The film 1 with the electrical microstructure 2 is then fastened directly on the fastening surface 11 without the adhesive layer 8. The fastening of the electrical microstructure 2 on the fastening surface 11 is carried out by the vulcanizing of the rubber material of the object 6. The film 1 is again removed as explained above.

1. A method for applying an electrical microstructure on or in an object, comprising:
applying the electrical microstructure on a flexible film to form a combination of the film with the electrical microstructure applied thereon; and
fastening the combination of the film with the electrical microstructure applied thereon on a fastening surface of the object by one or more of adhesive bonding on the object, and vulcanizing in the object.

2. The method as claimed in claim 1 further comprising, after the fastening step, removing the film fully or partially from the object.

3. The method as claimed in claim 2 wherein removing is performed by dissolving the film.

4. The method as claimed in claim 3 wherein dissolving is performed by one or more of wetting the film with a solvent which dissolves the film, and heating the film to dissolve the film.

5. The method as claimed in claim 1 wherein the film is perforated and/or comprises holes.

6. The method as claimed in claim 1 wherein the electrical microstructure is applied on the film by a vapor deposition process.

7. The method as claimed in claim 1 wherein the electrical microstructure comprises conductive tracks connecting surfaces for electrical and/or electronic components and/or passive electrical and/or electronic components.

8. The method as claimed in claim 1 wherein the step of applying the electrical microstructure on the film includes applying a layer of an interlayer material having electrical and/or electronic components embedded in recesses of the interlayer material onto the film, and then the electrical microstructure is applied to the interlayer material.

9. The method as claimed in claim 1 wherein the object on which the electrical microstructure is applied comprises a layer structure of at least two layers, and wherein the fastening surface is of one of the at least two layers, and wherein the other layers of the at least two layers are subsequently arranged so that the electrical microstructure is embedded between the at least two layers.

10. The method as claimed in claim 1 wherein the fastening step is performed with an adhesive which is cured by adding a curing agent.

11. The method as claimed in claim 10 wherein the curing agent also functions as a solvent that dissolves the film.

12. The method as claimed in claim 1 wherein the electrical microstructure comprises at least one sensor component.

13. An elastomer structure having at least one electrical microstructure adhesively bonded thereon or vulcanized in.

14. A fiber composite component having at least one electrical microstructure adhesively bonded thereon.

15. A tire having an electrical microstructure adhesively bonded or vulcanized in on the tire inner side or embedded between different layers of the tire.
